(19) United States
(12) Patent Application Publication
(10) Pub. No.: US 2015/0115314 A1
(43) Pub. Date: Apr. 30, 2015

(54) SEMICONDUCTOR DEVICE AND MANUFACTURING METHOD OF THE SAME

(71) Applicant: DENSO CORPORATION, Kariya-city, Aichi-Pref. (JP)

(72) Inventors: Kazuki Arakawa, Toyoake-city (JP); Masakiyo Sumitomo, Okazaki-city (JP); Masaki Matsui, Nagoya-city (JP); Yasushi Higuchi, Okazaki-city (JP); Kazuhiro Oyama, Nishitokyo-city (JP)

(21) Appl. No.: 14/381,238

(22) PCT Filed: Mar. 4, 2013
(86) PCT No.: PCT/JP2013/001332

§ 371 Date: Aug. 27, 2014

(30) Foreign Application Priority Data
Mar. 5, 2012 (JP) 2012-48006
Jun. 1, 2012 (JP) 2012-126006

(51) Int. Cl. H01L 29/423; H01L 29/66; H01L 29/739

(52) U.S. Cl. CPC H01L 29/42376; H01L 29/7397; H01L 29/66348
USPC 257/139; 438/138

(57) ABSTRACT

In a semiconductor device, a trench includes a first trench that has an opening portion on a surface of a base layer, and a second trench that is communicated with the first trench and in which a distance between opposed side walls is greater than opposed side walls of the first trench and a bottom portion is located in a drift layer. A wall surface of a connecting portion of the second trench connecting to the first trench is rounded. Therefore, an occurrence of a large electrical field concentration in the vicinity of the connecting portion between the first trench and the second trench can be suppressed. Also, when electrons are supplied from a channel region to the drift layer, it is less likely that a flow direction of the electrons will be sharply changed in the vicinity of the connecting portion. Therefore, an on-state resistance can be reduced.

### CROSS REFERENCE TO RELATED APPLICATIONS

This application is based on Japanese Patent Applications No. 2012-48006 filed on Mar. 5, 2012 and No. 2012-126006 filed on Jun. 1, 2012, the disclosures of which are incorporated herein by reference.

### TECHNICAL FIELD

The present disclosure relates to a semiconductor device formed with a trench-gate-type insulated gate bipolar transistor (hereinafter, simply referred to as the IGBT) and a manufacturing method of the semiconductor device.

### BACKGROUND ART

Conventionally, it has been proposed a structure of aiming to reduce an on-state resistance in a semiconductor device formed with a trench-gate-type IGBT, for example, as described in a patent literature 1.

In particular, an N⁻-type drift layer is formed on a P⁺-type semiconductor substrate forming a collector layer. Further, a P-type base layer is formed in a surface layer portion of the drift layer, and an N⁺-type emitter layer is formed in a surface layer portion of the base layer. Also, a plurality of trenches that passes through the base layer and the emitter layer and reaches the drift layer is formed.

The trench is formed from a surface of the base layer to a position reaching the drift layer. The trench has a bottom portion projecting in a direction parallel to a planar direction of the drift layer, within the drift layer. That is, the trench has a first trench located in the base layer and a second trench (bottom portion) in which a distance between opposed side walls of the second trench is greater than opposed side walls of the first trench. Therefore, between the adjacent trenches, a distance between the adjacent second trenches is smaller than a distance between the adjacent first trenches.

On a wall surface of each of the trenches, a gate insulation film and a gate electrode are sequentially formed. An emitter electrode is formed on the base layer and the emitter layer through an interlayer insulation film. The emitter electrode is electrically connected to the base layer and the emitter layer through contact holes formed in the interlayer insulation film. A collector electrode is formed on a rear surface of the collector layer, and is electrically connected to the collector layer.

In such a semiconductor device, when a predetermined voltage is applied to the gate electrode, electrons are supplied from the emitter layer to the drift layer, and holes are supplied from the collector layer to the drift layer. A resistance value of the drift layer is reduced due to conductivity modulation, resulting in an on state. In this case, since the distance between the adjacent second trenches is smaller than the distance between the adjacent first trenches, the holes supplied to the drift layer is less likely to escape through the base layer, as compared with a case where a distance between the adjacent trenches is constant with the distance of the adjacent first trenches. Therefore, an amount of holes can be accumulated in the drift layer, and hence the total number of electrons supplied to the drift layer is increased. Accordingly, the on-state resistance can be reduced.

### PRIOR ART LITERATURE

### Patent Literature

Patent Literature 1: JP 2008-60138 A (corresponding to US20080054351 A1)

### SUMMARY OF INVENTION

In the semiconductor device of the above-mentioned patent literature 1, however, an angle defined at a connecting portion between the first trench and the second trench is a right angle. When the semiconductor device is turned on, there is a possibility that a large electrical field concentration occurs in the vicinity of the connecting portion and thus the semiconductor device will be broken. Also, the electrons supplied from the emitter region to the drift layer flow along the side walls of the trench. Therefore, when the connecting portion between the first trench and the second trench has the right angle, the direction of flow of the electrons sharply changes in the vicinity of the connecting portion. As a result, the on-state resistance increases.

The present disclosure is made in view of the foregoing matters, and it is an object of the present disclosure to provide a semiconductor device that is capable of suppressing an occurrence of a large electrical field concentration in the vicinity of a connecting portion between a first trench and a second trench when being turned on and suppressing an on-state resistance, and a manufacturing method of the semiconductor device.

According to an aspect of the present disclosure, a semiconductor device includes a first conductivity-type drift layer, a second conductivity-type base layer disposed adjacent to a front surface of the drift layer, a plurality of trenches that extends through the base layer to the drift layer and is extended in a predetermined direction, a gate insulation film disposed on a wall surface of each of the trenches, a gate electrode disposed on the gate insulation film, a first conductivity-type emitter layer disposed in a surface layer portion of the base layer and on a side portion of the trench, a second conductivity-type collector layer disposed to be separated from the emitter layer through the drift layer, an emitter electrode electrically connected to the base layer and the emitter layer, and an a collector electrode electrically connected to the collector layer.

Further, in the semiconductor device, the trench has a first trench and a second trench. The first trench has an opening portion on a front surface of the base layer. The second trench is in communication with the first trench. A distance between opposed side walls of the second trench is greater than a distance between opposed side walls of the first trench. A bottom portion of the second trench is located in the drift layer. A wall surface of a connecting portion of the second trench connecting to the first trench is rounded.

Since the wall surface of the connecting portion of the second trench has a rounded shape, an occurrence of a large electrical field concentration in the vicinity of the connecting portion can be suppressed. In other words, an electrical field in the vicinity of the connecting portion can be reduced. Further, when electrons are supplied from the emitter layer to the drift layer, a sharp change of a flow direction of the electrons in the vicinity of the connecting portion can be suppressed. Therefore, an on-state resistance can be reduced.

Such a semiconductor device is manufactured by a manufacturing method described hereinafter.

In the manufacturing method, a step of forming the base layer adjacent to the front surface of the drift layer, a step of forming the first trench in the base layer by anisotropic etching, a step of forming a protection film on an inner wall surface of the first trench, a step of removing the protection film disposed on a bottom surface of the first trench, and a step of isotropic etching are performed. The manufacturing method is characterized by performing a step of forming the second trench that is in communication with the first trench and in which the wall surface of the connecting portion connecting to the first trench is rounded, a step of forming the gate insulation film on the inner wall surface of the trench, and a step of forming the gate electrode on the gate insulation film.

In the above method, since the second trench is formed by the isotropic etching, the wall surface of the connecting portion of the second trench can be rounded.

### BRIEF DESCRIPTION OF DRAWINGS

The above and other objects, features and advantages of the present disclosure will become more apparent from the following detailed description made with reference to the accompanying drawings, in which:

FIG. 1 is a cross-sectional view of a semiconductor device according to a first embodiment of the present disclosure;

FIG. 2 (a) to (d) of FIG. 2 are cross-sectional views illustrating a manufacturing process of the semiconductor device shown in FIG. 1;

FIG. 3 (a) to (d) of FIG. 3 are cross-sectional views illustrating a manufacturing process of the semiconductor device subsequent to (a) to (d) of FIG. 2;

FIG. 4 is a diagram illustrating a current concentration region and an electrical field concentration region in the semiconductor device shown in FIG. 1,

FIG. 5 is a cross-sectional view of a semiconductor device according to a second embodiment of the present disclosure;

FIG. 6 (a) to (c) of FIG. 6 are cross-sectional views illustrating a manufacturing process of the semiconductor device shown in FIG. 5;

FIG. 7 is a cross-sectional view of a semiconductor device according to a third embodiment of the present disclosure;

FIG. 8 (a) to (d) of FIG. 8 are cross-sectional views illustrating a manufacturing process of the semiconductor device shown in FIG. 7;

FIG. 9 (a) to (d) of FIG. 9 are cross-sectional views illustrating a manufacturing process of the semiconductor device subsequent to (a) to (d) of FIG. 8;

FIG. 10 is a cross-sectional view of a semiconductor device according to a fourth embodiment of the present disclosure; and

FIG. 11 is a plan view of a semiconductor device according to a fifth embodiment of the present disclosure.

### EMBODIMENTS FOR CARRYING OUT INVENTION

Hereinafter, embodiments of the present disclosure will be described with reference to the drawings. It is to be noted that, in the following description of the embodiments, the same or equivalent parts are designated with the same reference numbers.

### First Embodiment

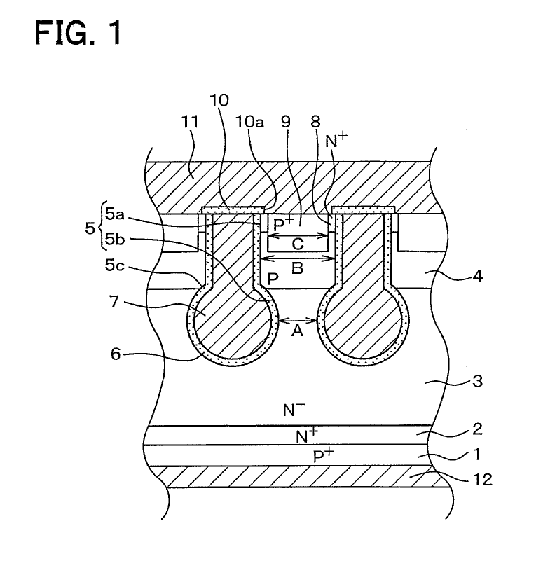

A first embodiment of the present disclosure will be described with reference to the drawings. As shown in FIG. 1, an N⁺-type buffer layer 2 is formed on a main surface of a semiconductor substrate forming a P⁺-type collector layer 1. The buffer layer 2 is not always necessary, but is provided to restrict expansion of a depletion layer so as to improve withstand voltage and performance of stationary loss.

An N⁻-type drift layer 3 is formed on the buffer layer 2, and a P-type base layer 4 is formed adjacent to a front surface (surface layer portion) of the drift layer 3. A plurality of trenches 5 is formed in a direction perpendicular to the main surface of the semiconductor substrate (hereinafter, simply referred to as the main surface of the collector layer 1), which forms the collector layer 1. The trenches 5 pass through the base layer 4 and reach the drift layer 3. The trenches 5 are extended in a stripe pattern in a predetermined direction (a direction perpendicular to a surface plane of FIG. 1).

Each of the trenches 5 is constructed of a first trench 5a that is formed in the base layer 4 and a second trench 5b that is in communication with the first trench 5a and extends from the vicinity of the interface between the base layer 4 and the drift layer 3 to the drift layer 3. That is, the second trench 5b of the present embodiment is formed from the base layer 4 to the drift layer 3, and a connecting portion 5c of the second trench 5b connecting to the first trench 5a is located in the base layer 4.

A portion of the second trench 5b lower than the connecting portion 5c has, in a cross-section of FIG. 1, an oval shape including a portion in which a distance between opposed side walls (the length in a left and right direction of FIG. 1) is greater than a distance between opposed side walls (the length in the left and right direction of FIG. 1) of the first trench 5a. That is, the second trench 5b has a shape (a shape having curvature) in which a bottom portion (bottom wall) and the side walls are rounded. In other words, the trench 5 has, in the cross-section of FIG. 1, a so-called pot shape.

Therefore, in the adjacent trenches 5, a shortest distance (A in FIG. 1) between the adjacent second trenches 5b is less than a distance (B in FIG. 1) of the adjacent first trenches 5a. Although not particularly limited, the shortest distance (A in FIG. 1) between the adjacent second trenches 5b can be, for example, approximately 0.5 μm, and the distance (B in FIG. 1) between the adjacent first trenches 5a can be, for example, approximately 1.5 μm.

In each of the trenches 5, the wall surface of the connecting portion 5c of the second trench 5b connecting to the first trench 5a has a rounded shape (a shape having curvature). That is, an upper end portion of the side wall of the second trench 5b (a portion connecting to the lower end of the first trench 5a) has a curved shape. For example, the curved shape is a shape convex outward of the second trench 5b.

On the side wall of each of the trenches 5, a gate insulation film 6 is formed. The gate insulation film 6 is made of a thermal oxide film or the like. A gate electrode 7 is formed on the gate insulation film 6. The gate electrode 7 is made of a conductive material, such as a doped poly-Si.

An N⁺-type emitter layer 8 is formed on a side portion of the first trench 5a in a surface layer portion of the base layer 4. A P⁺-type contact layer 9, which has a higher concentration than the base layer 4, is formed in the surface layer portion of the base layer 4 and at a portion that is between the adjacent first trenches 5a, opposite to the respective first trench 5a with respect to the emitter layer 8, and is opposed to the drift layer 3 located between the adjacent second trenches 5b. In other words, the contact layer 9 is formed directly on the drift layer 3 located between the second trenches 5b, in the surface layer portion of the base layer 4.

In the present embodiment, the contact layer 9 is formed to a position deeper than the emitter layer 8. As shown by C in FIG. 1, a length of the contact layer 9 (hereinafter, simply referred to as the width) in a direction that is perpendicular to an extended direction of the trench 5 and parallel to the main surface of the collector layer 1 is greater than the shortest distance (A in FIG. 1) of the adjacent second trenches 5b. The width of the contact layer 9 is, for example, approximately 0.8 μm.

An emitter electrode 11 is formed on the surface of the emitter layer 8, the surface of the contact layer 9 and the surface of the gate electrode 7 through an interlayer insulation film 10. The emitter electrode 11 is electrically connected to the emitter layer 8 and the contact layer 9 through a contact hole 10a formed in the interlayer insulation film 10. On a rear surface side of the collector layer 1, a collector electrode 12 is formed to be electrically connected to the collector layer 1.

The semiconductor device of the present embodiment has the structure described hereinabove. It is to be noted that, in the present embodiment, the N⁺-type and the N⁻-type correspond to a first conductivity-type, and the P-type and the P⁺-type correspond to a second conductivity-type.

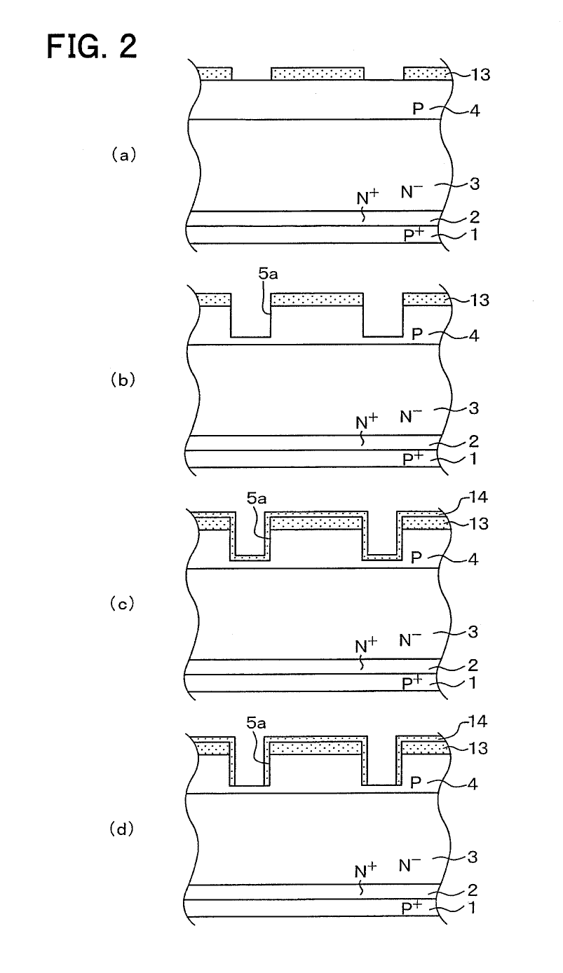

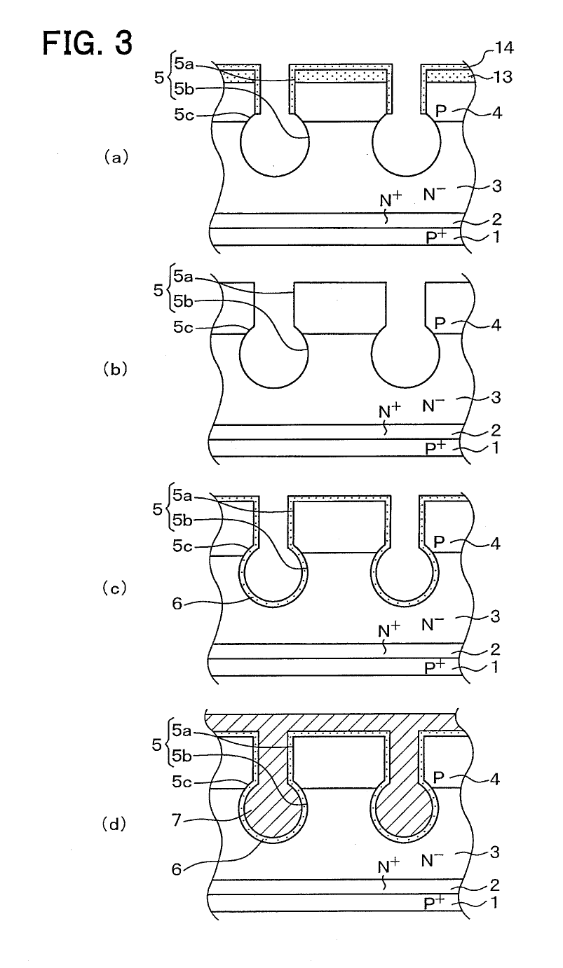

Next, a manufacturing method of the above-described semiconductor device will be described with reference to FIG. 2 and FIG. 3.

First, as shown in (a) of FIG. 2, a substrate in which the buffer layer 2, the drift layer 3 and the base layer 4 are sequentially formed on the semiconductor substrate forming the collector layer 1 is prepared. For example, the base layer 4 is formed by performing ion implantation of an impurity to the front surface of the drift layer 3. Thereafter, an etching mask 13, which is made of a silicon oxide film or the like, is formed on the base layer 4 by a chemical vapor deposition (hereinafter, simply referred to as the CVD) technique or the like, and then this etching mask 13 is patterned to form openings in regions where the first trenches 5a are to be formed.

Next, as shown in (b) of FIG. 2, an anisotropic etching, such as reactive ion etching (hereinafter, simply referred to as the RIE), is performed using the etching mask 13 to form the first trenches 5a. In the present embodiment, since the first trench 5a has a structure in which the first trench 5a is ended within the base layer 4 (an end opposite to the opening portion of the first trench 5a is located within the base layer 4), the first trench 5a is formed to a position in the vicinity of the interface between the base layer 4 and the drift layer 3. Thereafter, if necessary, a step of eliminating damage on the wall surface of the first trench 5a formed is performed by performing a chemical dry etching (CDE) or the like.

Next, as shown in (c) of FIG. 2, an etching mask 14 such as a SiN film is formed on the wall surface of the first trench 5a by the CDV technique or the like. It is to be noted that, although the etching mask 13 is remained as it is in this step, the etching mask 14 may be formed after the etching mask 13 is removed.

Next, as shown in (d) of FIG. 2, by performing the anisotropic etching such as the RIE, the etching mask 14 disposed on the bottom surface of the first trench 5a is selectively removed while remaining the etching mask 14 disposed on the side wall of the first trench 5a. In the present embodiment, the etching mask 14 corresponds to a protection film.

Thereafter, as shown in (a) of FIG. 3, the isotropic etching is performed to the bottom surface of the first trench 5a using the etching mask 14 so as to form the second trench 5b in which the distance between the opposed side walls is greater than the distance between the opposed side walls of the first trench 5a. As such, the trench 5 having the pot shape is formed.

Since the second trench 5b is formed by the isotropic etching, the wall surface of the connecting portion 5c of the second trench 5b, the bottom portion of the second trench 5b, and the side wall of the second trench 5b have the rounded shape, and have a circular shape in a cross-section.

Next, as shown in (b) of FIG. 3, the etching masks 13, 14 are removed. Then, as shown in (c) of FIG. 3, the gate insulation film 6 is formed on the wall surface of the trench 5. The gate insulation film 6 is, for example, formed by the CVD technique or the thermal oxidation.

Next, as shown in (d) of FIG. 3, a doped poly-Si is film-formed on the gate insulation film 6 to form the gate electrode 7.

Thereafter, a conventional general manufacturing process for a semiconductor device is performed. After the insulation film film-formed on the base layer and the doped poly-Si are removed, the emitter layer 8, the contact layer 9, the interlayer insulation film 10, the emitter electrode 11, the collector electrode 12 and the like are formed. Thus, the above-described semiconductor device shown in FIG. 1 is produced.

For example, in a case where the emitter layer 8 and the contact layer 9 are formed by ion implantation, an acceleration voltage of ion-implanting an impurity for forming the contact layer 9 is greater than an acceleration voltage of ion-implanting an impurity for forming the emitter layer 8. Thus, the contact layer 9 can be formed to a position deeper than the emitter layer 8.

Next, an operation of such a semiconductor device will be described.

Firstly, an on-state will be described. In the above-described semiconductor device, when a predetermined voltage (for example, 15V) is applied to a gate electrode 7, a portion of the base layer 4 contacting the trench 5 becomes the N-type, and thus an inversion layer is formed. Further, electrons are supplied from the emitter layer 8 to the drift layer 3 through the inversion layer, and holes are supplied from the collector layer 1 to the drift layer 3. As a result, the resistance value of the drift layer 3 is reduced due to conductivity modulation, resulting in the on-state.

In this case, the minimum distance (A in FIG. 1) between the adjacent second trenches 5b is smaller than the distance (B in FIG. 1) between the adjacent first trenches 5a. Therefore, it becomes difficult that the holes supplied to the drift layer 3 escape through the base layer 4, as compared with a case where the distance between the adjacent trenches 5 is constant with the distance (B in FIG. 1) between the adjacent first trenches 5a. Therefore, a large amount of holes can be accumulated in the drift layer 3. With this, the total amount of the electrons supplied to the drift layer 3 is increased. As such, the on-state resistance can be reduced.

The wall surface of the connecting portion 5c has a rounded shape. Therefore, it is less likely that a large electrical field concentration will occur in the vicinity of the connecting portion 5c. In other words, the electrical field in the vicinity of the connecting portion 5c can be reduced.

The electrons are supplied from the emitter layer 8 to the drift layer 3 along the wall surface of the trench 5. Since the wall surface of the connecting portion 5c is rounded, it is less likely that the flow direction of the electrons will sharply change in the vicinity of the connecting portion 5c. As such, the on-state resistance can be reduced.

Next, an off-state will be described. When a predetermined voltage (for example, 0V) is applied to the gate electrode 7, the inversion layer formed in the base layer 4 disappears. The supply of the electrons from the emitter layer 8 is terminated, and the supply of the holes from the collector layer 1 is terminated. The holes accumulated in the drift layer 3 escapes from the emitter electrode 11 through the base layer 4.

In the present embodiment, the contact layer 9 is formed right above the drift layer 3 located between the adjacent second trenches 5b, in the surface layer portion of the base layer 4. Also, the contact layer 9 is formed to be deeper than the emitter layer 8, and the width (C in FIG. 1) of the contact layer 9 is greater than the minimum distance (A in FIG. 1) between the adjacent second trenches 5b. Therefore, the holes can be easily escaped from the emitter electrode 11 through the contact layer 9, as compared with a case where the contact layer 9 is shallower than the emitter layer 8 or the width of the contact layer 9 is smaller than the minimum distance (A in FIG. 1) of the adjacent second trenches 5b. As such, an occurrence of latch-up can be suppressed.

As described above, in the present embodiment, the wall surface of the connecting portion 5c has the rounded shape. Therefore, an occurrence of a large electrical field concentration in the vicinity of the connecting portion 5c can be suppressed. In other words, the electrical field in the vicinity of the connecting portion 5c can be reduced.

The electrons are supplied from the emitter layer 8 to the drift layer 3 along the wall surface of the trench 5. Since the wall surface of the connecting portion 5c has the rounded shape, it is less likely that the flow direction of the electrons will sharply change in the vicinity of the connecting portion 5c. Therefore, the on-state resistance can be reduced. Also, it is less likely that hot carriers will be injected to the gate insulation film 6. Therefore, reliability of the gate insulation film 6 can be improved.

In the second trench 5b, the bottom portion and the side wall have the rounded shape. Therefore, an occurrence of a large electrical field concentration in the vicinity of the bottom portion or the side wall of the second trench 5b can be suppressed. As such, the gate withstand voltage of the semiconductor device can be further improved.

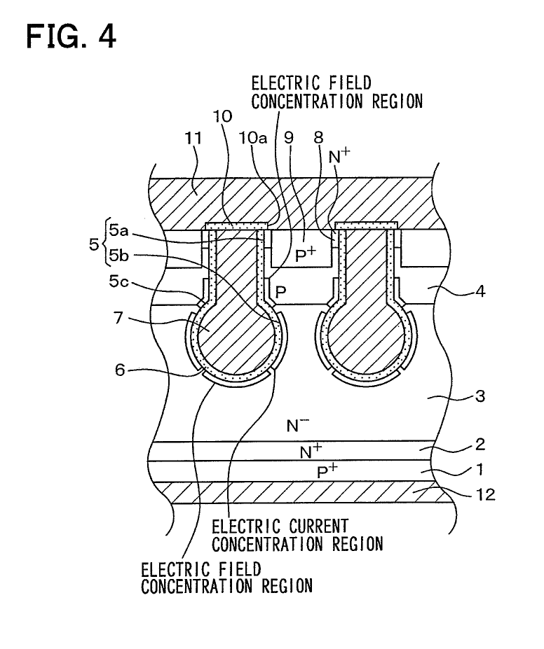

In the above-described semiconductor device, since the second trench 5b has the rounded shape, it is concerned that the electrical field will easily concentrate in a region in the vicinity of the connecting portion 5c and in a region in the vicinity of the bottom portion of the second trench 5b, as shown in FIG. 4. On the other hand, a current concentration region is formed in the vicinity of the portion of the second trench 5b that forms the portion where the distance between the adjacent second trenches 5b is the minimum, in the drift layer 3. In other words, the current concentration region is formed in the vicinity of the region contacting the portion between the connecting portion 5c and the bottom portion of the second trench 5b, in the drift layer 3. In the above-described semiconductor device, therefore, since the electrical field concentration region and the current concentration region are different, a maximum electric power is reduced, and the resistance can be improved.

Since the connecting portion 5c (for example, at least the upper end portion of the connecting portion 5c) is located in the base layer 4, an occurrence of a leak current can be suppressed. When the gate insulation film 6 is formed, stress concentrates on the connecting portion 5c. Therefore, a defect is easily generated in a region in the vicinity of the connecting portion 5c. When the connecting portion 5c is located within the drift layer 3, there is a possibility that a defect is generated in a region of the vicinity of the connecting portion 5c within the drift layer 3. In this case, there is a possibility that a depletion layer of PN junction formed by the drift layer 3 and the base layer 4 reaches the defect at a time of turning on. When the depletion layer reaches the defect at the time of turning on, the electrons and the holes are bonded or separated, resulting in an occurrence of a leak current.

In the present embodiment, on the other hand, the connecting portion 5c is located in the base layer 4. Therefore, even if the defect is generated, it is less likely that the depletion layer will reach the defect at the time of turning on. As such, the occurrence of the leak current can be suppressed.

The contact layer 9 is deeper than the emitter layer 8, and the width (C in FIG. 1) of the contact layer 9 is greater than the minimum distance (A in FIG. 1) between the adjacent second trenches 5b. Therefore, the holes can be easily escaped from the emitter electrode 11 through the contact layer 9 at the time of turning off, as compared with a case where the contact layer 9 is shallower than the emitter layer 8 or the width of the contact layer 9 is smaller than the minimum distance (A in FIG. 1) between the adjacent second trenches 5b. As such, an occurrence of latch-up can be suppressed.

### Second Embodiment

A second embodiment of the present disclosure will be described. In the present embodiment, the shape of the second trench 5b is modified from that of the first embodiment. The other structures are similar to those of the first embodiment, and thus descriptions thereof will be omitted.

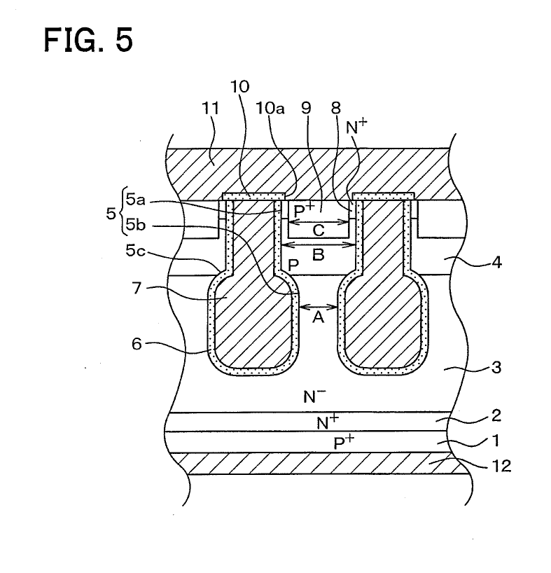

As shown in FIG. 5, in the semiconductor device of the present embodiment, a portion of the side wall of the second trench 5b does not have a rounded shape. In other words, the portion of the side wall of the second trench 5b has a shape without having curvature, and extends in a direction parallel to a direction that is perpendicular to the main surface of the collector layer 1.

Likewise, a portion of the bottom portion of the second trench 5b does not have a rounded shape. In other words, the portion of the bottom portion of the second trench 5b has a shape without having curvature, and extends in a direction parallel to the main surface of the collector layer 1.

The minimum distance (A in FIG. 5) between the adjacent second trenches 5b is the same as that of the first embodiment. However, the length of the second trench 5b in the direction perpendicular to the main surface of the collector layer 1 (the length in the up and down direction in FIG. 5) is greater than that of the second trench 5b of the first embodiment.

Such a semiconductor device is manufactured as follows.

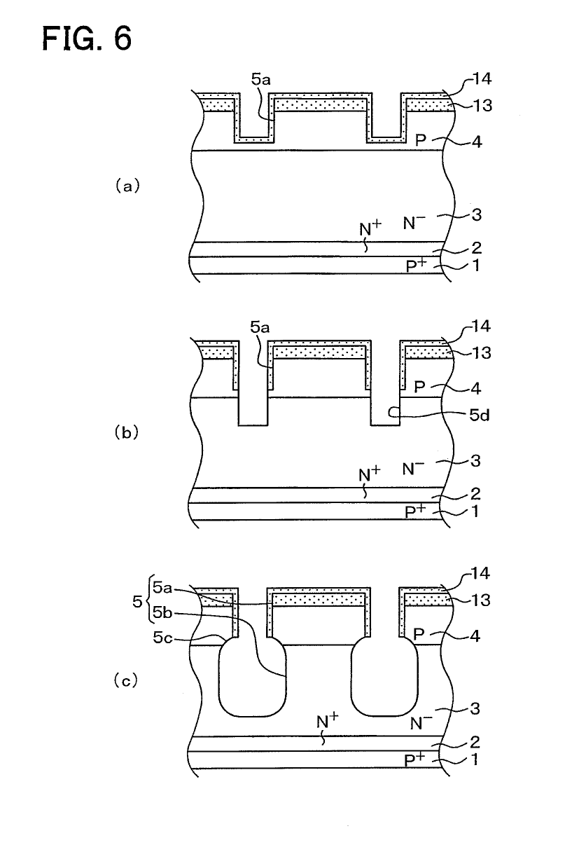

As shown in (a) of FIG. 6, the first trench 5a is formed by performing the steps similar to (a) to (c) of FIG. 2. Thereafter, the etching mask 14, which is made of the SiN film or the like, is formed on the wall surface of the first trench 5a by the CVD technique or the like.

Thereafter, as shown in (b) of FIG. 6, the anisotropic etching, such as the RIE technique, is performed again to the bottom surface of the first trench 5a to remove the etching mask 14 disposed on the bottom surface of the first trench 5a and to form a third trench 5d reaching the drift layer 3. Since the third trench 5d is formed by the anisotropic etching, a distance between opposed side walls is constant.

Next, as shown in (c) of FIG. 6, the third trench 5d is isotropic-etched so that the opposed side walls of the third trench 5d are backed, thereby forming the second trench 5b.

The second trench 5b is formed by performing the isotropic etching to the third trench 3d, and portions of the side walls and the bottom portion are backed isotropic. Therefore, the portions of the side walls and the bottom portion are formed into the shape without having roundness. In the case where the isotropic etching is performed so that the minimum distance (A in FIG. 5) between the adjacent second trenches 5b is the same as that of the first embodiment, in the present embodiment, since the isotropic etching is performed for the third trench 5d, the length of the second trench 5b in the direction perpendicular to the main surface of the collector layer 1 is greater than that of the second trench 5b of the first embodiment.

Thereafter, similar to the above-described first embodiment, the etching masks 13, 14 are removed. Then, the gate insulation film 6 and the gate electrode 7 are formed, and the emitter layer 8, the contact layer 9, the interlayer insulation film 10, the emitter electrode 11, the collector electrode 12 are formed. As such, the above-described semiconductor device shown in FIG. 5 is manufactured.

In this case, the length of the second trench 5b in the direction perpendicular to the main surface of the collector layer 1 is elongated. Therefore, the region of the drift layer 3 disposed between the adjacent second trenches 5b is increased, and thus the holes accumulated in the drift layer 3 are hardly escaped through the base layer 4. Therefore, the on-state resistance can be further reduced, and the effects similar to those of the above-described first embodiment can be achieved.

### Third Embodiment

A third embodiment of the present disclosure will be described. In the present embodiment, the gate insulation film 6 formed in the second trench 5b of the second embodiment is formed by a thermal oxidation so that the thickness of the gate insulation film 6 formed in the second trench 5b is greater than the thickness of the gate insulation film 6 formed in the first trench 5a. The other structures are the same as the first embodiment, and thus descriptions thereof will be omitted.

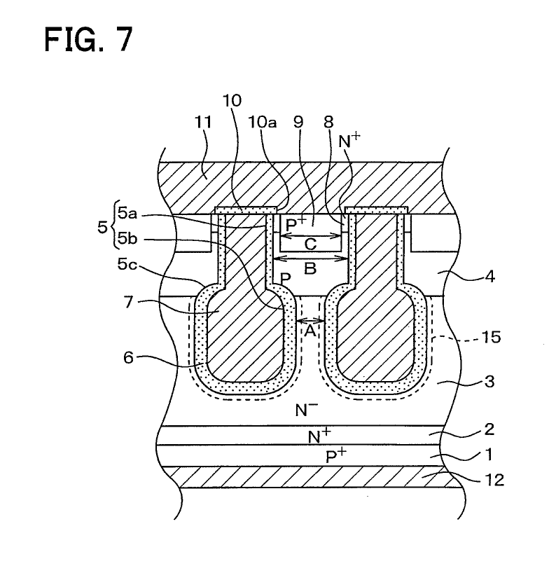

As shown in FIG. 7, in the semiconductor device of the present embodiment, the gate insulation film 6 formed in the second trench 5b is provided by the thermal oxidation, and the thickness of the gate insulation film 6 formed in the second trench 5b is greater than the thickness of the gate insulation film 6 formed in the first trench 5a. Further, the thickness of the gate insulation film 6 formed in the vicinity of the connecting portion 5c of the second trench 5b connecting to the first trench 5a is also substantially the same as the thickness of the gate insulation film 6 formed in the second trench 5b, and is greater than the thickness of the gate insulation film 6 formed in the first trench 5a. In a portion of the drift layer 3 contacting the second trench 5b, a pile-up layer 15 is formed by segregation of an N-type impurity.

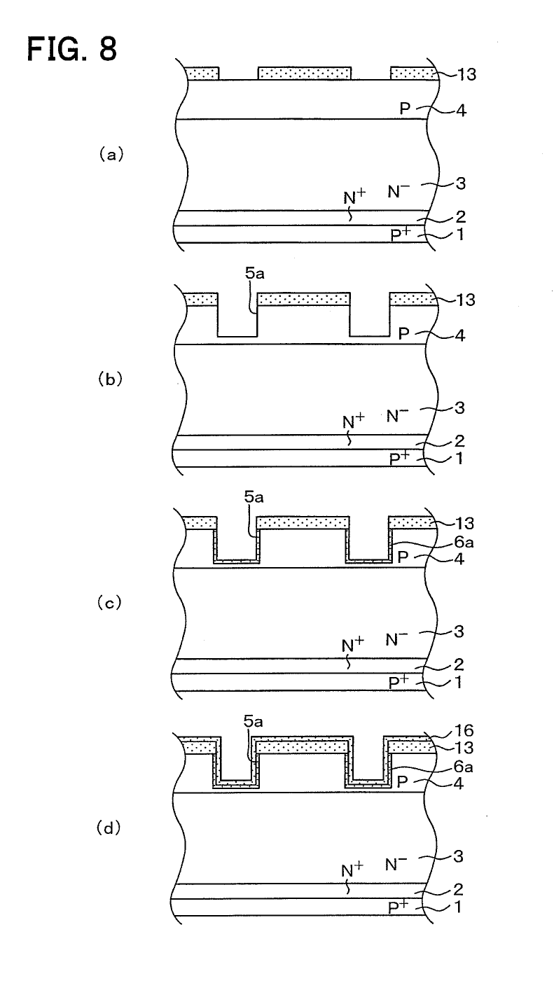

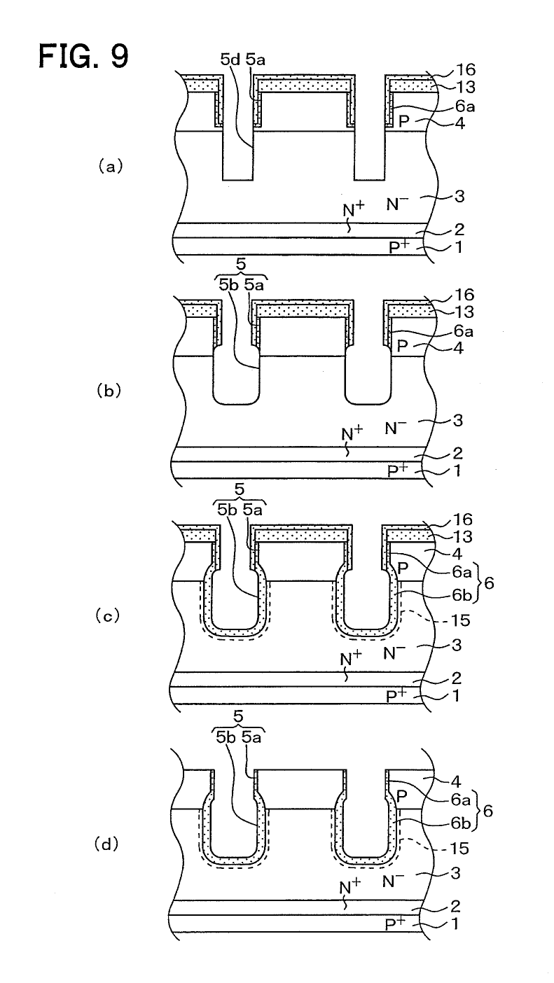

Next, a manufacturing method of such a semiconductor device will be described with reference to FIGS. 8 and 9.

Firstly, as shown in (a) and (b) of FIG. 8, the first trench 5a is formed by performing the similar steps to (a) and (b) of FIG. 2.

Next, as shown in (c) of FIG. 8, an insulation film 6a for forming the gate insulation film 6 is formed in the first trench 5a by the thermal oxidation. In the present embodiment, the insulation film 6a is a thermal oxide film formed by the thermal oxidation. Alternatively, the insulation film 6a may be a thermal oxide film formed by the CVD technique or the like.

Thereafter, as shown in (d) of FIG. 8, an oxygen impermeability film 16 is formed for restricting the first trench 5a from being thermally oxidized in a step of (c) of FIG. 9, which will be described later. In the present embodiment, a SiN film or the like is formed by the CVD technique to cover the first trench 5a. That is, after the completion of the step of (d) of FIG. 8, the insulation film 6a and the oxygen impermeability film 16 are sequentially piled up.

Next, as shown in (a) of FIG. 9, the oxygen impermeability film 16 and the insulation film 6a formed on the bottom surface of the first trench 5a are removed, and the third trench 5d reaching the drift layer 3 is formed, by performing the similar step of (b) of FIG. 6.

Next, as shown in (b) of FIG. 9, the third trench 5d is isotropic-etched by performing the similar step to (c) of FIG. 6, so that the opposed side walls of the third trench 5d are backed. Thus, the second trench 5b is formed.

Thereafter, as shown in (c) of FIG. 9, the thermal oxide film 6b is formed in the second trench 5b for forming the gate insulation film 6 thicker than the insulation film 6a formed in the first trench 5a. In particular, the oxygen impermeability film 16 is disposed in the first trench 5a and the thermal oxide film is not formed in the first trench 5a. Therefore, the thermal oxide film 6b thicker than the insulation film 6a is formed by performing wet-oxidation, for example, at 1150° C. for a heating time suitably adjusted. The thermal oxide film 6b of this step may be formed by dry-oxidation.

By performing this step, the n-type impurity in the drift layer 3 is piled up (segregated), and thus the pile-up layer 15 is formed at the portion contacting the second trench 5b in the drift layer 3.

Next, as shown in (d) of FIG. 9, the oxygen impermeability film 16 and the etching mask 13 are removed. As a result, the trench 5 is in a state where the gate insulation film 6 is formed in the trench 5. Thereafter, the gate electrode 7, the emitter layer 8, the contact layer 9, the interlayer insulation film 10, the emitter electrode 11, the collector electrode 12 are formed, in the similar manner to the above-described second embodiment. Thus, the above-described semiconductor device shown in FIG. 7 is manufactured.

In this case, since the pile-up layer 15 is formed at the portion of the drift layer 3 contacting the second trench 5b, the holes accumulated in the drift layer 3 further hardly escape through the base layer 4 due to the pile-up layer 15. Therefore, a larger amount of the holes can be accumulated in the drift layer 3, and the on-state resistance can be further reduced.

### Fourth Embodiment

A fourth embodiment of the present disclosure will be described. In the present embodiment, the depth of the trench 5 is modified from that of the trench 5 of the first embodiment. The other structures are the same as those of the first embodiment, and thus description thereof will be omitted.

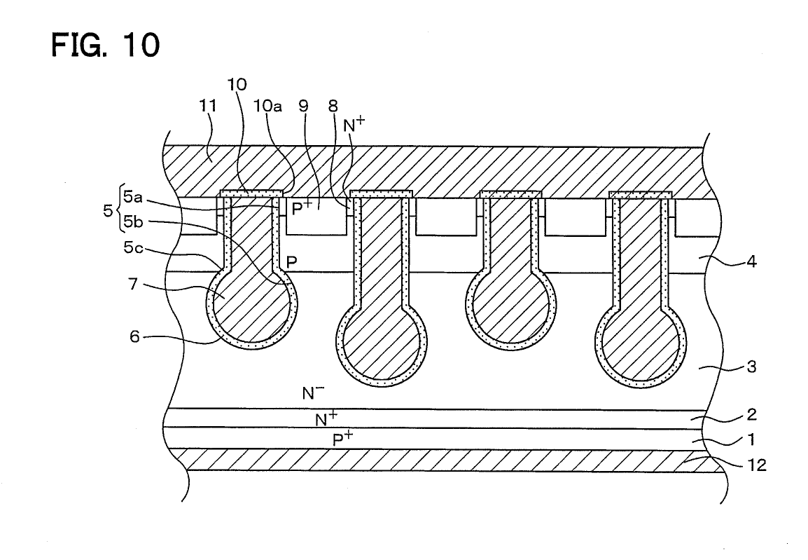

As shown in FIG. 10, in the semiconductor device of the present embodiment, the depth of the trenches 5 is different. In particular, between the adjacent trenches 5, one is deeper than the other. In the deeper trench 5, the connecting portion 5c of the second trench 5b connecting to the first trench 5a is located in the drift layer 3.

In such a semiconductor device, since the adjacent trenches 5 have different depths, it is less likely that the adjacent second trenches 5b will contact (communicate) with each other when the second trenches 5b are formed.

### Fifth Embodiment

A fifth embodiment of the present disclosure will be described. In the present embodiment, the trenches 5 are formed into a lattice shape, relative to the first embodiment. The other structures are similar to those of the first embodiment, and descriptions thereof will be omitted.

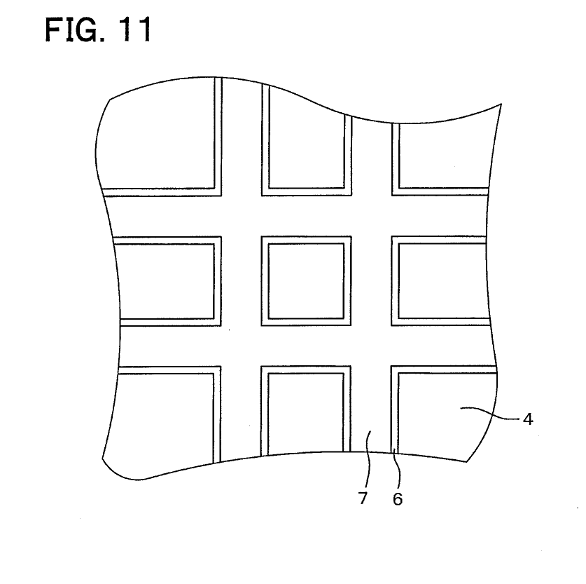

As shown in FIG. 11, in the present embodiment, in addition to the trenches 5 extended in the predetermined direction, the trenches 5 perpendicular to the predetermined direction are formed. That is, the trenches 5 are formed into the lattice shape. In FIG. 11, illustration of the emitter layer 8, the contact layer 9, the interlayer insulation film 10 and the emitter electrode 11 are omitted.

In this case, the holes accumulated in the drift layer 3 further hardly escape through the base layer 4. Therefore, a larger amount of the holes can be accumulated in the drift layer 3, and the on-state resistance can be further reduced.

### Other Embodiments

In each of the embodiments described above, it is exemplarily described that the first conductivity-type is the N-type, and the second conductivity-type is the P-type. However, the first conductivity-type may be the P-type and the second conductivity-type may be the N-type.

In each of the embodiments described above, the second trench 5b may be located only in the drift layer 3. That is, the first trench 5a may be formed to reach the drift layer 3 and the connecting portion 5c may be located in the drift layer 3. Also in such a semiconductor device, since the connecting portion 5c between the first trench 5a and the second trench 5b has the rounded shape, an occurrence of a large electrical field concentration in the vicinity of the connecting portion 5c can be suppressed, and the on-state resistance can be reduced.

In each of the embodiments described above, the gate insulation film 6 and the gate electrode 7 may be formed in the trench 5 after the emitter layer 8 and the contact layer 9 are formed.

In each of the embodiments described above, the semiconductor device having the contact layer 9 is described. However, the contact layer 9 is not always necessary. Also, it is not necessary that the contact layer 9 is formed deeper than the emitter layer 8. The width (C in FIGS. 1 and 4) may be shorter than the minimum distance (A in FIGS. 1 and 4) between the adjacent second trenches 5b. Also in such a semiconductor device, an occurrence of a large electrical field concentration in the vicinity of the connecting portion 5c can be suppressed, and the on-state resistance can be reduced.

In each of the embodiment described above, the example in which the contact layer 9 is formed to the position deeper than the emitter layer 8 by changing the acceleration voltage is described. For example, the contact layer 9 may be formed as follows. Namely, when very small trenches are formed on a surface where the contact layer 9 is to be formed, even if the contact layer 9 is ion-implanted at a relatively low acceleration voltage, the contact layer 9 can be formed to the position deeper than the emitter layer 8.

In each of the embodiments described above, the manufacturing method of the semiconductor device using the semiconductor substrate forming the semiconductor substrate is described. For example, the manufacturing method may be performed as follows. Namely, the semiconductor substrate forming the drift layer 3 is firstly prepared, and the base layer 4 is formed on the main surface of the semiconductor substrate. Thereafter, an impurity is ion-implanted from the rear surface of the semiconductor substrate as well as a thermal treatment is performed, thereby to form the collector layer 1. In such a manufacturing method, the collector layer 1 may be formed after the semiconductor substrate is made into a thin film by grinding or the like.

In each of the embodiments described above, the vertical-type semiconductor device in which the electric current flows in a thickness direction of the drift layer 3 is described. Alternatively, the semiconductor device may be a lateral-type in which the electric current flows in the planar direction of the drift layer 3. Namely, the collector layer 1 may be formed at a position separated from the base layer 4 in the surface layer portion of the drift layer 3.

The semiconductor device may be provided by combining each of the embodiments described above. For example, a semiconductor device in which the pile-up layer 15 is formed may be provided by combining the first or second embodiment with the third embodiment. Also, a semiconductor device in which the trenches 5 have the different depths may be provided by the second or third embodiment with the fourth embodiment. Further, a semiconductor device in which the trenches 5 are formed into the lattice shape may be provided by combining the second, third or fourth embodiment with the fifth embodiment.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. A semiconductor device comprising:
a first conductivity-type drift layer;
a second conductivity-type base layer disposed adjacent to a front surface of the drift layer;
a plurality of trenches passing through the base layer to reach the drift layer, and being extended in a predetermined direction;
a gate insulation film formed on a wall surface of each of the trenches;
a gate electrode disposed on the gate insulation film;
a first conductivity-type emitter layer disposed on a side portion of the trench in a surface layer portion of the base layer;
a second conductivity-type collector layer disposed to be separated from the emitter layer through the drift layer;
an emitter electrode electrically connected to the base layer and the emitter layer; and
a collector electrode electrically connected to the collector layer, wherein
the trench includes a first trench that has an opening portion on a surface of the base layer and a second trench that is communicated with the first trench and in which a distance between opposed side walls of the second trench is greater than a distance between opposed side walls of the first trench, and a bottom portion of the second trench is located in the drift layer, and
a wall surface of a connecting portion of the second trench connecting to the first trench is rounded.

2. The semiconductor device according to claim 1, wherein
the bottom portion of the second trench is rounded.

3. The semiconductor device according to claim 1, wherein
a side wall of the second trench between the connecting portion and the bottom portion is rounded.

4. The semiconductor device according to claim 1, wherein
the trench is disposed such that the second trench extends from the base layer to the drift layer, and the connecting portion is located in the base layer.

5. The semiconductor device according to claim 1, wherein
a portion of the drift layer contacting the second trench is formed with a pile-up layer.

6. A manufacturing method of a semiconductor device, the semiconductor device comprising:
a first conductivity-type drift layer;
a second conductivity-type base layer disposed adjacent to a front surface of the drift layer;
a plurality of trenches passing through the base layer to reach the drift layer, and being extended in a predetermined direction;
a gate insulation film formed on a wall surface of each of the trenches;
a gate electrode disposed on the gate insulation film;
a first conductivity-type emitter layer disposed on a side portion of the trench in a surface layer portion of the base layer;
a second conductivity-type collector layer disposed to be separated from the emitter layer through the drift layer;
an emitter electrode electrically connected to the base layer and the emitter layer; and
a collector electrode electrically connected to the collector layer, wherein
the trench includes a first trench that has an opening portion on a surface of the base layer and a second trench that is communicated with the first trench and in which a distance between opposed side walls of the second trench is greater than a distance between opposed side walls of the first trench, and a bottom portion of the second trench is located in the drift layer, and
a wall surface of a connecting portion of the second trench connecting to the first trench is rounded, the manufacturing method comprising:
forming the base layer adjacent to the front surface of the drift layer;
forming the first trench in the base layer by anisotropic etching;
forming a protection film on an inner wall surface of the first trench;
removing the protection film disposed on a bottom surface of the first trench;
forming the second trench that is communicated with the first trench and in which the wall surface of the connecting portion is rounded, by performing a step including isotropic etching, thereby forming the trench;
forming the gate insulation film on the inner wall surface of the trench; and
forming the gate electrode on the gate insulation film.

7. The manufacturing method of the semiconductor device according to claim 6, wherein
the forming of the second trench includes forming a third trench that is communicated with the first trench by performing an anisotropic etching, and forming the second trench by increasing a distance between opposed side walls of the third trench by performing an isotropic etching to the third trench.
